(19) United States
(12) Patent Application Publication
(10) Pub. No.: US 2019/0346673 A1
(43) Pub. Date: Nov. 14, 2019

(54) SELF-SUPPORT ELECTROWETTING DISPLAY AND PREPARATION METHOD THEREFOR

(71) Applicants: SOUTH CHINA NORMAL UNIVERSITY, Guangzhou,Guangdong (CN); SHENZHEN GUOHUA OPTOELECTRONICS CO., LTD., Shenzhen, Guangdong (CN); ACADEMY OF SHENZHEN GUOHUA OPTOELECTRONICS, Shenzhen, Guangdong (CN)

(72) Inventors: Guofu Zhou, Guangzhou, Guangdong (CN); Biao TANG, Guangzhou, Guangdong (CN); Hongwei JIANG, Guangzhou, Guangdong (CN); Yingying DOU, Guangzhou, Guangdong (CN); Ying ZHOU, Guangzhou, Guangdong (CN)

(21) Appl. No.: 16/475,937

(22) PCT Filed: Nov. 15, 2017
(86) PCT No.: PCT/CN2017/110985

§ 371 Date: Jul. 3, 2019

(30) Foreign Application Priority Data
Jan. 17, 2017 (CN) 20170036365.3

(51) Int. Cl. G02B 26/00; G03F 7/20

(52) U.S. Cl. CPC G02B 26/005; G03F 7/2043

(57) ABSTRACT

An electrowetting display device includes an upper substrate, and a lower substrate including a first light-transmitting substrate, a conducting layer, a hydrophobic insulating layer and a pixel wall structure, wherein an upper surface of the pixel wall structure is provided with a support structure. A preparation method for the electrowetting display device, including providing an upper substrate and a lower substrate; preparing a pixel wall structure on the lower substrate; and preparing a support structure on the pixel wall structure.

### FIELD

The present disclosure relates to the field of electrowetting technologies, and more particularly, to a self-supported electrowetting display and a preparation method therefor.

### BACKGROUND

The so-called wetting refers to a process in which a fluid on a solid surface is replaced by another fluid. A liquid can be spread on the solid surface, because there is an expanding tendency on the solid-liquid contact surface, that is to say, the wetting is due to an adhesive force of the liquid to the solid surface greater than a cohesive force therein. In a situation that the liquid cannot be spread on the solid surface and the contact surface has a tendency to shrink into a sphere, which is non-wetting, if the adhesive force of the liquid to the solid surface is less than the cohesive force therein.

As shown in FIG. 1, a general electrowetting display device structure mainly includes an upper substrate and a lower substrate, wherein the upper substrate includes an upper glass substrate 1′, a first electrode 2′ and a sealant 3′, and the lower substrate includes a lower glass substrate 9′, a second electrode 8′, a hydrophobic insulating layer 7′ (generally a fluorinated polymer) and pixel walls 6′. A pattern of the pixel wall 6′ defines a pixel of the display device. An area between the pixel walls 6′ is a display area. The pixel is filled with two immiscible fluids of a non-polar solution 5′ (ink) and a polar solution 4′ (electrolyte solution). The hydrophilia and the hydrophobicity of the electrolyte solution 4′ on the hydrophobic insulating layer 7′ are changed by applying a voltage to the polar solution 4′ and the second electrode 8′ of the lower substrate, thus allowing the spreading and shrinking of the non-polar solution 5′ to achieve a display effect.

The pixel wall 6′ and the non-polar solution 5′ are covered with the polar electrolyte solution 4′, wherein the polar solution 4′ is continuous in an electrowetting device and is not separated like the non-polar solution 5′, and the polar solution 4′ is in conduction with the first electrode 2′. When a voltage is applied between the first electrode 2′ and the second electrode 8′, the wettability of the polar solution 4′ on a surface of the hydrophobic insulating layer 7′ is changed from a hydrophobic state to a hydrophilic state, so that the polar solution 4′ wets the surface of the hydrophobic insulating layer 7′, and the non-polar solution 5′ is pushed to a corner in a pixel grid to realize an opening state. When the voltage is removed, the hydrophobicity of the polar electrolyte solution 4 on the surface of the hydrophobic insulate layer is restored, and the non-polar solution 5′ is spread again to realize a closing process. In an example of a pixel size of 150 μm*150 μm, a height of the pixel wall in the electrowetting display device is 6 μm, a thickness of the non-polar solution 5′ is 5.5 μm to 6.6 μm, and a thickness of the sealant 3′ is 40 μm, so that a thickness of the polar electrolyte solution 4′ is also about 40 μm. When the voltage is applied, the non-polar solution 5′ is shrunk, and the height is changed to 25 μm. With reference to FIG. 2, a distance between the first electrode 2′ of the upper substrate and the non-polar liquid 5′ is 15 μm to 40 μm. Due to an effect of an external atmospheric pressure, centers of the upper and lower substrates are easy to deform, thus causing the first electrode 2′ to contact with the non-polar solution 5′, accumulation 10′ of the non-polar solution 5′ on the surface of the first electrode 2′, overturning 11′ of the non-polar solution 5′, or accumulation of the non-polar solution 5′ on the lower substrate, so as to cause failure of a whole display device. Therefore, there is an urgent need for an electrowetting display device that can support the upper and lower substrates, in order to solve the problem of ink overturning or accumulation caused by bending and deformation of the upper and lower substrates, and to realize a flexibility of the electrowetting display device.

At present, generally there is a risk that the upper and lower substrates are deformed and subsided in the middle for such a box-like display device. For example, in order to achieve high-quality display effect in a preparation process of a liquid crystal display panel, a thickness of a liquid crystal layer needs to be accurately controlled to achieve good light regulation of the whole liquid crystal layer. Therefore, a spacer needs to be added between the upper and lower substrates for supporting. For example, a micro-sphere or a micro-rod used as the spacer in the liquid crystal display panel is added between the upper and lower substrates of the liquid crystal display panel, so as to support the upper and lower substrates via a size of the micro-sphere or the micro-rod. However, the method of supporting the upper and lower substrates by adding the micro-sphere or the micro-rod is not suitable for the electrowetting display device, because the micro-sphere or the micro-rod is easy to fall into the pixel grid and to contact with the non-polar solution, which can cause the non-polar solution to accumulate or turn over the pixel wall. In addition, mixing several ultraviolet polymerized polymers and initiators together in a liquid crystal, and then forming the spacer through ultraviolet irradiation are also the method for supporting the upper and lower substrates in the liquid crystal display panel. The method for preparing the spacer by ultraviolet curing can also be applied to the electrowetting display device in theory, but the risks in an actual operation process lie in that: for example, an ultraviolet polymerization material or a photoinitiator can be mutually dissolved with the non-polar solution or a color solute in non-polar solution can be extracted; the ultraviolet polymerization material or the photoinitiator is not fully reacted in a polymerization process with residual substances in the polar electrolyte solution, which affects an electric conductivity thereof and a wettability of the polar electrolyte solution on the hydrophobic insulating layer in an electrified state; in the polymerization process, a mask plate is required to define a position of the polymer; and an alignment accuracy of the mask plate, a thickness of the mask plate, and refraction of ultraviolet light by the thickness of the mask plate and the thickness of the upper support plate 1 can all cause deviation of an position where the polymer is actually formed, thus being contacted with the non-polar solution.

At present, the thickness of the sealant can be increased to partially solve the problem of subsidence of the center of the electrowetting display device, therefore the thickness of a sealant frame needs to be much larger than deformation quantities of the upper and lower substrates. But the method still cannot solve the problem of subsidence for an electrowetting device or a flexible device that has a large-size display panel with ultra-thin glass as the upper and lower substrate.

### SUMMARY

In the present disclosure is to provide a self-supported electrowetting display and a preparation method therefor are provided to solve the above technical problems.

The technical solutions in the present disclosure are as follows.

An electrowetting display device includes an upper substrate and a lower substrate. The lower substrate includes a first light-transmitting substrate, a conducting layer, a hydrophobic insulating layer and a pixel wall structure. An upper surface of the pixel wall structure is provided with a support structure.

In some detailed embodiments, the support structure includes a plurality of support pillars.

In a preferred embodiment of the solutions above, the support pillars are arranged on junctions of mutually perpendicular walls in the pixel wall structure.

In a preferred embodiment of the solutions above, the support pillars are cylindrical or polygonal.

In some detailed embodiments, a material of the support structure is a photoresist.

In some detailed embodiments, a material of the support structure is a material of the pixel wall structure or a material with stronger hydrophilicity than the pixel wall structure.

In some detailed embodiments, a height of the support structure is less than or equal to a distance between the upper surface of the pixel wall structure and the upper substrate.

The present disclosure further provides a preparation method for the electrowetting display device, which includes a step of preparing the pixel wall structure on the lower substrate, wherein the method further includes a step of preparing the support structure on the pixel wall structure.

In some detailed embodiments, preparing the support structure on the pixel wall includes preparing the support structure in a photoetching process.

The present disclosure has the beneficial effects as follows.

Aiming at the problem that the electrowetting display is easy to cause device failure due to deformations of the upper substrate and the lower substrate, the present disclosure provides a self-supported electrowetting display and a preparation method therefor. The support structure is directly prepared on the pixel wall to avoid a problem that the support structure falls into a pixel grid, so that a basic structure of the electrowetting display is not changed generally, and the performance of the display device is not affected. No component need to be added into a polar electrolyte solution, so that component residual can be avoided, and pollution of two functional solutions will not occur. The thickness of the sealant can be reduced, thus the thickness of the whole display device can be reduced for achieving an ultrathin display.

### BRIEF DESCRIPTION OF THE DRAWINGS

FIG. 1 is a sectional structure diagram of a general electrowetting display device.

FIG. 2 is a schematic diagram illustrating deformation of a substrate of the general electrowetting display device.

FIG. 3 is a schematic diagram illustrating a preparation process of a self-supported electrowetting display according to a first embodiment.

FIG. 4 is a three-dimensional structure diagram of a partial support structure according to a second embodiment.

FIG. 5 is a top view of the partial support structure according to the second embodiment.

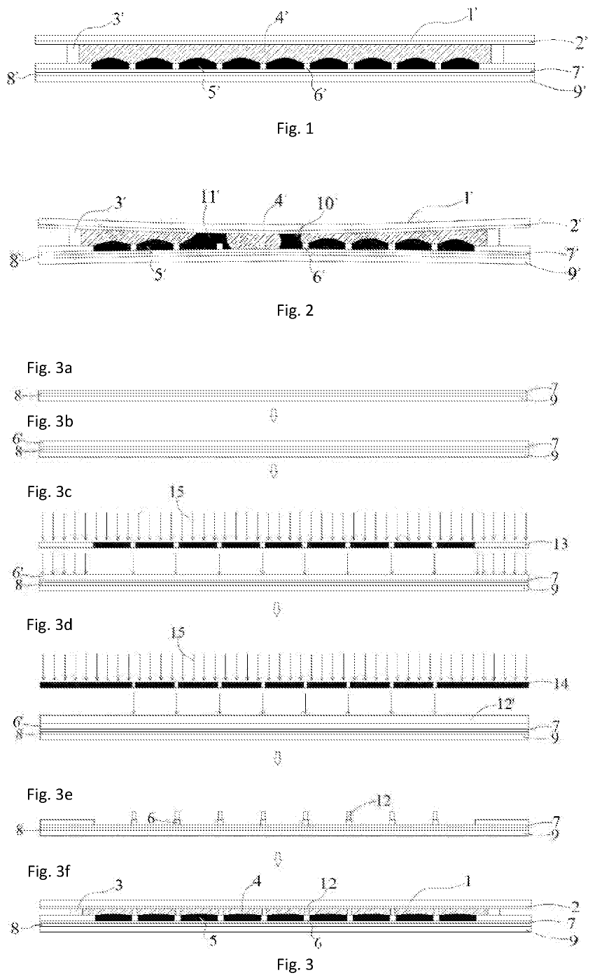

### DETAILED DESCRIPTION

### First Embodiment

With reference to a preparation process shown in FIG. 3, a self-supported electrowetting display is prepared.

Firstly, as shown in FIG. 3a, a conducting layer 8 is prepared on a first light-transmitting substrate 9. A hydrophobic insulating layer 7 is prepared on the conducting layer 8. The hydrophobic insulating layer 7 can be a single layer structure or a composite layer structure of an insulating layer and a hydrophobic layer. In a preferred embodiment, the hydrophobic insulating layer 7 is a single layer structure, which is obtained by the following steps: coating a solution of the hydrophobic insulating layer 7 on a surface of the first light-transmitting substrate 9 having the conducting layer 8 via spin coating, scraping coating, slit coating, silk-screen printing, flexographic printing and other methods, performing thermal curing processing to obtain the hydrophobic insulating layer 7, and modifying a surface of the hydrophobic insulating layer 7 by a reactive ion etching machine to reduce a hydrophobicity of the surface. In the modification step, a photoresist material can be formed a film on the surface of the hydrophobic insulating layer 7 to increase an adhesive force on the surface of the hydrophobic insulating layer 7, and improve a wettability of the photoresist material on the surface. With reference to FIG. 3b, the photoresist material 6′ is uniformly coated on the surface of the hydrophobic insulating layer 7 by a coating method such as spin coating, scraping coating, slit coating, etc. With reference to FIG. 3c, a first mask plate 13 is placed above and aligned with the lower substrate, and the first mask plate 13 is irradiated by parallel ultraviolet rays 15. The first mask plate 13 has a preset pattern of a pixel wall structure, and a part of the parallel ultraviolet rays can pass through the first mask plate 13 and irradiate on the photoresist material 6′ to expose and cure the photoresist material 6′. After the exposure, a second layer of photoresist material 12′ is coated by any coating method such as spin coating, scraping coating, slit coating, etc. The second layer of photoresist material 12′ is the same as the first layer of photoresist material 6′. Then a second mask plate 14 is placed above and aligned with the lower substrate, and the second mask plate 14 is provided with a pattern of a supporting structure corresponding to a pixel wall position. The second mask plate 14 is irradiated by the parallel ultraviolet rays 15, and a part of the parallel ultraviolet rays can pass through the second mask plate 14 and irradiate on the photoresist material 12′ to expose and cure the photoresist material 12′. After the exposure, with reference to FIG. 3e, the pixel wall structure 6 and the support structure 12 are obtained by developing with a high concentration KOH solution. Because the patterns on the second mask plate 14 are all at the positions corresponding to the pixel wall 6, the exposure process of the support structure cannot affect a non-exposed area of the pixel wall 6, so that the support structure 12 is prepared on the pixel wall structure 6. The support structure 12 can include support pillars, and the support pillars can be of any shape, such as being cylindrical or polygonal. Then, the lower substrate is placed in a high-temperature environment to enable the hydrophobic insulating layer 7 to reach a glass transition temperature and restore the hydrophobicity of the surface of the hydrophobic insulating layer 7. Finally, a non-polar solution 5 is filled in the pixel grid under an environment of a polar electrolyte solution 4, and subsequently the upper substrate consisting of a second light-transmitting substrate 1, the conducting layer 2 and the sealant 3 is aligned and pressed with the lower substrate to complete the preparation process of the electrowetting device, thus obtaining the self-supported electrowetting display with the structure, as shown in FIG. 3f. A height of the support structure 12 is equal to a distance between the upper surface of the pixel wall structure 6 and the upper substrate, so that the support structure 12 is contacted with the conducting layer 2 to support the upper and lower substrates. The electrolyte solution 4 is still continuous in the self-supported electrowetting display, and the support structure 12 cannot affect the continuity of the electrolyte solution 4.

### Second Embodiment

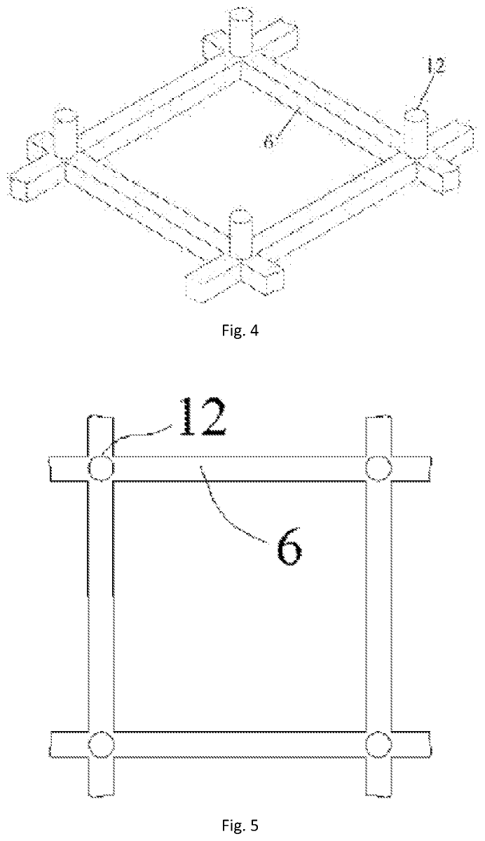

Refer to FIG. 4 and FIG. 5. FIG. 4 is a three-dimensional structure diagram of a partial support structure. FIG. 5 is a top view of the partial support structure. This embodiment is basically the same as the first embodiment, except that the support structure 12 is on a junction of mutually perpendicular walls in the pixel wall structure 6. The support structure 12 includes cylindrical support pillars. A material of the support structure 12 is a photoresist material with a stronger hydrophilicity than the pixel wall structure 6. The property of the material of the support structure 12 shall be similar to that of the material of the pixel wall structure 6. The material of the support structure 12 can be adjusted according to a requirement of a filling effect of the actual non-polar solution 5. The position and number of the support structures 12 can be controlled by a preset pattern of the second mask plate 14, so that densities and layouts of different support structures 12 can be designed for different sizes and different types of devices.

1. An electrowetting display device, comprising
an upper substrate and
a lower substrate comprising a first light-transmitting substrate, a conducting layer, a hydrophobic insulating layer and a pixel wall structure,
wherein an upper surface of the pixel wall structure is provided with a support structure.

2. The electrowetting display device according to claim 1, wherein the support structure comprises a plurality of support pillars.

3. The electrowetting display device according to claim 2, wherein the support pillars are arranged on junctions of mutually perpendicular walls in the pixel wall structure.

4. The electrowetting display device according to claim 2, wherein the support pillars are cylindrical or polygonal.

5. The electrowetting display device according to claim 1, wherein the support structure consists of a material of photoresist.

6. The electrowetting display device according to claim 1, wherein a material of the support structure consists of a material that is the same as the pixel wall structure.

7. The electrowetting display device according to claim 1, wherein a height of the support structure is less than or equal to a distance between the upper surface of the pixel wall structure and the upper substrate.

8. A preparation method for an electrowetting display device, comprising:
providing an upper substrate and a lower substrate;
forming a first light-transmitting substrate, a conducting layer and a hydrophobic insulating layer from the lower substrate;
preparing a pixel wall structure on the lower substrate; and
preparing a support structure on the pixel wall structure.

9. The preparation method for the electrowetting display device according to claim 8, wherein preparing the support structure on the pixel wall structure comprises preparing the support structure in a photoetching process.

10. The electrowetting display device according to claim 1, wherein a material of the support structure consists of a material with stronger hydrophilicity than the pixel wall structure.

11. A preparation method for an electrowetting display device, comprising:
providing an upper substrate and a lower substrate;
forming a first light-transmitting substrate, a conducting layer and a hydrophobic insulating layer from the lower substrate;
preparing a pixel wall structure on the lower substrate; and
preparing a plurality of support pillars on junctions of mutually perpendicular walls in the pixel wall structure.

12. The preparation method for the electrowetting display device according to claim 11, wherein preparing the support structure on the pixel wall structure comprises preparing the support structure in a photoetching process.
